(19) United States
(12) Patent Application Publication
(10) Pub. No.: US 2025/0365995 A1
(43) Pub. Date: Nov. 27, 2025

(54) SEMICONDUCTOR DEVICE AND PREPARATION METHOD THEREFOR

(71) Applicant: CSMC TECHNOLOGIES FAB2 CO., LTD., Wuxi (CN)

(72) Inventors: Sen ZHANG, Wuxi (CN); Nailong HE, Wuxi (CN); Jingchuan ZHAO, Wuxi (CN)

(21) Appl. No.: 18/871,694

(22) PCT Filed: Feb. 8, 2023
(86) PCT No.: PCT/CN2023/074934

§ 371 Date: Dec. 4, 2024

(30) Foreign Application Priority Data
Jun. 17, 2022 (CN) 202210689556.0

(51) Int. Cl. H10D 1/68; H10D 1/00; H10D 64/00

(52) U.S. Cl. CPC H10D 1/68; H10D 1/042; H10D 64/111

(57) ABSTRACT

In one aspect, a semiconductor device includes: a first metal layer disposed on a substrate; a dielectric layer disposed on a side of the first metal layer distant from the substrate; a second metal layer disposed on a side of the dielectric layer distant from the first metal layer, the potential of the second metal layer being higher than the potential of the first metal layer; and a metal ring disposed on a side of the dielectric layer distant from the first metal layer, the metal ring being arranged around an outer side of the second metal layer. A portion of the metal ring is located in the dielectric layer.

### CROSS-REFERENCE TO RELATED APPLICATIONS

This application claims priority to Chinese Patent Application No. 2022106895560, entitled “SEMICONDUCTOR DEVICE AND PREPARATION METHOD THEREFOR” and filed with the China Patent Office on Jun. 17, 2022, the entire content of which is incorporated herein by reference.

### TECHNICAL FIELD

The present application relates to the field of integrated circuit technologies, and in particular, to a semiconductor device and a preparation method therefor.

### BACKGROUND

Galvanic isolation refers to a manner of preventing a current from flowing directly from one region to another region in a circuit, that is, no path for direct current flow is established between two regions. Initially, optically coupled isolators are mostly used as isolators. With the continuous advancement of a complementary metal oxide semiconductor (CMOS) technology, a digital isolation technology has begun to make great strides and is gradually recognized by the market. High reliability and a high speed of the digital isolation technology far exceed limits of the conventional optical coupling technology.

Currently, a common CMOS high-voltage isolation capacitor is prepared by using a surface dielectric stacking process, including first depositing a layer of metal on a surface of a silicon wafer as a lower plate of the high-voltage isolation capacitor, then growing a thick layer of silicon dioxide or a composite layer of silicon dioxide and silicon nitride on the metallized lower plate as a dielectric layer of the high-voltage isolation capacitor, and finally depositing a layer of metal on the dielectric layer as an upper plate of the high-voltage isolation capacitor.

However, in the conventional high-voltage isolation capacitor, the dielectric layer at an edge of the upper plate is prone to premature breakdown, which reduces the service life of the high-voltage isolation capacitor.

### SUMMARY

According to various exemplary embodiments of the present application, a semiconductor device and a preparation method therefor are provided.

In a first aspect, the present application provides a semiconductor device, including:
a substrate;
a first metal layer disposed on the substrate;
a dielectric layer disposed on a side of the first metal layer away from the substrate;
a second metal layer disposed on a side of the dielectric layer away from the first metal layer, a potential of the second metal layer being higher than a potential of the first metal layer; and
a metal ring disposed on a side of the dielectric layer away from the first metal layer, the metal ring being arranged around an outer side of the second metal layer.
A portion of the metal ring is arranged in the dielectric layer.

In the above semiconductor device, the metal ring is arranged on an outer periphery of the second metal layer, and a portion of the metal ring extends into the dielectric layer. In this way, on the one hand, through a field plate effect of the metal ring, electric field distribution at an edge of the second metal layer is optimized, thereby reducing electric field intensity at the edge of the second metal layer. On the other hand, a portion of the metal ring is arranged in the dielectric layer, which is beneficial to movement of movable charges between the metal ring and the second metal layer and minimizes hindrance to the movement of the charges caused by defects on a surface of the dielectric layer, thereby further optimizing the electric field distribution at the edge of the second metal layer, reducing the electric field intensity at the edge of the second metal layer, increasing a withstand voltage of the semiconductor device, preventing premature breakdown of the dielectric layer, and prolonging the service life of the semiconductor device.

In an embodiment, the metal ring includes a first part and a second part connected to each other. The first part is embedded in the dielectric layer. The second part is located on the side of the dielectric layer away from the first metal layer.

In an embodiment, in a thickness direction of the dielectric layer, a thickness of the first part ranges from about 400 nm to about 500 nm.

In an embodiment, a thickness of the second part is equal to a thickness of the second metal layer, and an upper surface of the second part is flush with an upper surface of the second metal layer.

In an embodiment, an orthographic projection of the second part on an upper surface of the dielectric layer covers an orthographic projection of the first part on the upper surface of the dielectric layer.

In an embodiment, a first spacing is defined between the second metal layer and the metal ring adjacent to the second metal layer. The first spacing ranges from about 2 μm to about 5 μm.

In an embodiment, the semiconductor device includes a plurality of metal rings.

The plurality of metal rings are arranged around the second metal layer and spaced apart from each other.

In an embodiment, a second spacing is defined between two adjacent metal rings. The second spacing being equal to the first spacing.

In an embodiment, the semiconductor device further includes a passivation layer arranged on a side of the dielectric layer adjacent to the second metal layer. The passivation layer covers part of a surface of the second metal layer, a surface of the metal ring, and an exposed surface of the dielectric layer.

In an embodiment, the semiconductor device further includes isolation structures arranged on the substrate. A capacitor formed by the first metal layer, the dielectric layer, and the second metal layer is arranged between adjacent isolation structures.

In a second aspect, the present application further provides a preparation method for a semiconductor device, including:
forming a first metal layer on a substrate;
forming a dielectric layer on the first metal layer;
forming a metal ring on the dielectric layer, a portion of the metal ring being arranged in the dielectric layer; and
forming a second metal layer on the dielectric layer, a potential of the second metal layer being higher than a potential of the first metal layer. The metal ring is arranged around an outer side of the second metal layer.

In an embodiment, the forming the metal ring on the dielectric layer includes:
providing a trench in the dielectric layer:
forming a first part of the metal ring in the trench; and
forming a second part connected to the first part on the dielectric layer, to form the metal ring.

In an embodiment, the method further includes, subsequent to the forming the second metal layer on the dielectric layer:
forming a passivation layer on part of a surface of the second metal layer, the passivation layer further covering a surface of the metal ring and an exposed surface of the dielectric layer.

According to the above preparation method for a semiconductor device, on the one hand, through a field plate effect of the metal ring, electric field distribution at an edge of the second metal layer is optimized, thereby reducing electric field intensity at the edge of the second metal layer. On the other hand, a portion of the metal ring is arranged in the dielectric layer, which is beneficial to movement of movable charges between the metal ring and the second metal layer and minimizes hindrance to the movement of the charges caused by defects on a surface of the dielectric layer, thereby further optimizing the electric field distribution at the edge of the second metal layer, reducing the electric field intensity at the edge of the second metal layer, increasing a withstand voltage of the semiconductor device, preventing premature breakdown of the dielectric layer, and prolonging the service life of the semiconductor device.

### BRIEF DESCRIPTION OF THE DRAWINGS

In order to more clearly illustrate the technical solutions in embodiments of the present application or the conventional art, the accompanying drawings used in the description of the embodiments or the conventional art will be briefly introduced below. It is apparent that, the accompanying drawings in the following description only illustrate some embodiments of the present application, and other drawings can be obtained by those of ordinary skill in the art from the provided drawings without creative efforts.

FIG. 1 is a schematic view of a semiconductor device according to an embodiment of the present application.

FIG. 2 is a perspective view of a partial structure of the semiconductor device in FIG. 1.

FIG. 3 is a top view of FIG. 2.

FIG. 4 is a schematic view of simulation of electric field distribution of the semiconductor device not provided with a metal ring according to an embodiment of the present application.

FIG. 5 is a schematic view of simulation of electric field distribution of the semiconductor device in which a metal ring is provided on a surface of a dielectric layer according to an embodiment of the present application.

FIG. 6 is a schematic view of simulation of electric field distribution of the semiconductor device in which a portion of the metal ring is located in the dielectric layer according to an embodiment of the present application.

FIG. 7 is a flowchart of a preparation method for a semiconductor device according to an embodiment of the present application.

FIG. 8 is a schematic view of the semiconductor device after formation of the dielectric layer according to an embodiment of the present application.

FIG. 9 is a flowchart of preparation of a metal ring of the semiconductor device according to an embodiment of the present application.

FIG. 10 is a schematic view of the semiconductor device after formation of a trench according to an embodiment of the present application.

FIG. 11 is a schematic view of the semiconductor device after formation of a first part of the metal ring according to an embodiment of the present application.

FIG. 12 is a schematic view of the semiconductor device after formation of a second part of the metal ring according to an embodiment of the present application.

FIG. 13 is a schematic view of the semiconductor device after formation of a second metal layer according to an embodiment of the present application. and

FIG. 14 is a schematic view of the semiconductor device after formation of a passivation layer according to an embodiment of the present application.

### ILLUSTRATION FOR REFERENCE SIGNS

100: semiconductor device: 110: substrate: 120: first metal layer: 130: dielectric layer: 131: trench: 140: second metal layer: 150: metal ring: 151: first part: 152: second part: 160: passivation layer: 170: isolation structure: 180: interconnection structure.

### DETAILED DESCRIPTION

For easy understanding of the present disclosure, a more comprehensive description of the present disclosure is given below with reference to the accompanying drawings. Preferred embodiments of the present disclosure are illustrated in the accompanying drawings. However, the present disclosure may be implemented in many different forms and is not limited to the embodiments described herein. Rather, these embodiments are provided to make the contents disclosed in the present disclosure more thoroughly and comprehensive.

Unless otherwise defined, all technical and scientific terms used herein have the same meaning as commonly understood by those of ordinary skill in the art to which the present disclosure belongs. The terms used in the specification of the present disclosure are intended only to describe particular embodiments and are not intended to limit the present disclosure.

It should be understood that when an element or layer is referred to as being “on”, “adjacent to”, “connected to”, or “coupled to” another element or layer, the element or layer may be directly on, adjacent to, connected to, or coupled to the another element or layer, or an intermediate element or layer may be provided therebetween. On the contrary, when an element is referred to as being “directly on”, “directly adjacent to”, “directly connected to”, or “directly coupled to” another element or layer, no intermediate element or layer may be provided therebetween. It should be understood that although terms such as first, second, and third may be used to describe various elements, components, regions, layers, doping types, and/or portions, the elements, components, regions, layers, doping types, and/or portions may not be limited to such terms. Such terms are used only to distinguish one element, component, region, layer, doping type, or portion from another element, component, region, layer, doping type, or portion. Thus, without departing from the teaching of the present disclosure, a first element, component, region, layer, doping type, or portion may be referred to as a second element, component, region, layer, or portion.

Spatial relationship terms such as “under”, “underneath”, “below”, “beneath”, “over”, and “above” may be used to describe a relationship between one element or feature and another element or feature illustrated in the figures. It should be understood that, in addition to the orientations illustrated in the figures, the spatial relationship terms are intended to further include different orientations of the device in use and operation. For example, if the device in the figures is flipped, an element or a feature described as “below”, “underneath” or “under” another element or feature may be oriented as “on” the another element or feature. Thus, the exemplary terms “below” and “under” may include two orientations of above and below. In addition, the device may be additionally orientated (e.g., rotated by 90-degree or orientated in other ways), and thus spatial descriptors used herein may be interpreted accordingly.

In use, the singular forms of “a/an”, “one”, and “the” may also include plural forms, unless otherwise clearly specified in the context. It should be further understood that the terms “composed of” and/or “including/comprising” specify the presence of the features, integers, steps, operations, components, portions or any combination thereof, but may not exclude the presence or addition of one or more of other features, integers, steps, operations, components, portions or any combination thereof. In addition, in this specification, the term “and/or” may include any and all combinations of associated listed items.

Embodiments of the present disclosure are described herein with reference to cross-sectional views that are schematic views of ideal embodiments (and intermediate structures) of the present disclosure, so that variants in the shapes shown due to, for example, manufacturing techniques and/or tolerances can be expected. Therefore, embodiments of present disclosure should not be limited to the specific shapes of the regions shown herein, and includes shape deviations due to, for example, manufacturing techniques. For example, an implantation region shown as a rectangle generally has rounded or curved features and/or an injected concentration gradient at its edges, rather than a binary change from the implantation region to a non-implantation region. Similarly, a buried region formed by implantation may result in some implantations in the region between the buried region and the surface through which the implantation takes place. Therefore, the regions shown in the figures are schematic in nature, their shapes do not represent the actual shape of the region of the device, and do not limit the scope of the application.

It is to be noted that a high electric field region at an edge of a plate forming a high-voltage capacitor limits a breakdown voltage of the high-voltage capacitor. Description is based on an example in which an upper plate of the high-voltage capacitor is connected to a high potential. On the one hand, electric field intensity between the upper plate and a lower plate is relatively uniform, while electric field intensity at an edge of the upper plate is generally higher. On the other hand, due to an influence of a preparation process of the high-voltage capacitor, such as plasma bombardment or etching, an upper surface of the dielectric layer is prone to defects, especially a portion near the edge of the upper plate. Superposition of the above two factors causes the dielectric layer at the edge of the upper plate to be prone to premature breakdown, which reduces the service life of the high-voltage isolation capacitor.

In view of the problem that the dielectric layer at the edge of the upper plate in the conventional high-voltage isolation capacitor is prone to premature breakdown, embodiments of the present application provide a semiconductor device and a preparation method therefor.

The embodiments of the present application provide a semiconductor device. The semiconductor device may be a high-voltage isolation capacitor. The semiconductor device 100 includes a substrate 110. The substrate 110 may be made of monocrystalline silicon, polycrystalline silicon, amorphous silicon, silicon-germanium compound, silicon-on-insulator

(SOI), low temperature poly-silicon (LTPS), or the like, or made of other materials known to those skilled in the art. The substrate 110 may provide a supporting foundation for structures on the substrate 110.

As shown in FIG. 1, the semiconductor device 100 further includes a first metal layer 120 disposed on the substrate 110, a dielectric layer 130 disposed on a side of the first metal layer 120 away from the substrate 110, a second metal layer 140 disposed on a side of the dielectric layer 130 away from the first metal layer 120, and a metal ring 150 disposed on a side of the dielectric layer 130 away from the first metal layer 120. The metal ring 150 is arranged around an outer side of the second metal layer 140, and a portion of the metal ring 150 is located in the dielectric layer 130.

The dielectric layer 130 includes an insulating dielectric. For example, the dielectric layer 130 may be made of silicon dioxide, silicon nitride, silicon oxynitride, or the like. Both the first metal layer 120 and the second metal layer 140 are configured to be electrically connected to an external circuit. The potential of the second metal layer 140 is higher than the potential of the first metal layer 120.

According to the above semiconductor device 100, through a field plate effect of the metal ring 150, electric field distribution at an edge of the second metal layer 140 is optimized, thereby reducing electric field intensity at the edge of the second metal layer 140. It may be understood as follows: a capacitor is formed between the metal ring 150 and the second metal layer 140, this capacitor may create a field plate effect; and an electric field of this capacitor evenly disperses an electric field at the edge of the second metal layer 140, thereby suppressing a peak of the electric field at the edge of the second metal layer 140, increasing a withstand voltage of the semiconductor device 100, preventing premature breakdown of the dielectric layer 130, and prolonging the service life of the semiconductor device 100.

It may alternatively be understood as follow. The second metal layer 140 is connected to a high potential (compared with the first metal layer 120), and part of charges originally flowing between the second metal layer 140 and the dielectric layer 130 may flow laterally between the second metal layer 140 and the metal ring 150, thereby changing electric field distribution at the edge of the second metal layer 140, reducing electric field intensity at the edge of the second metal layer 140, and increasing a breakdown voltage of the semiconductor device 100.

In addition, due to the influence of the preparation process, for example, plasma bombardment, a surface of the dielectric layer 130 is prone to damages, resulting in defects on the surface of the dielectric layer 130. A portion of the metal ring 150 is arranged in the dielectric layer 130, so that movable charges, when moving from the metal ring 150 to the second metal layer 140 in the dielectric layer 130, may move from directly below the defects to the metal ring 150, which reduces movement paths and minimizes hindrance to the movement of the charges caused by the defects on the surface of the dielectric layer 130, thereby further optimizing the electric field distribution at the edge of the second metal layer 140, reducing the electric field intensity at the edge of the second metal layer 140, increasing the withstand voltage of the semiconductor device 100, preventing premature breakdown of the dielectric layer 130, and prolonging the service life of the semiconductor device 100.

The substrate 110 may be further provided with isolation structures 170. A capacitor formed by the first metal layer 120, the dielectric layer 130, and the second metal layer 140 may be arranged between adjacent isolation structures 170. In addition, the substrate 110 may be further provided with an interconnection structure 180 configured to energize electronic components on the substrate 110.

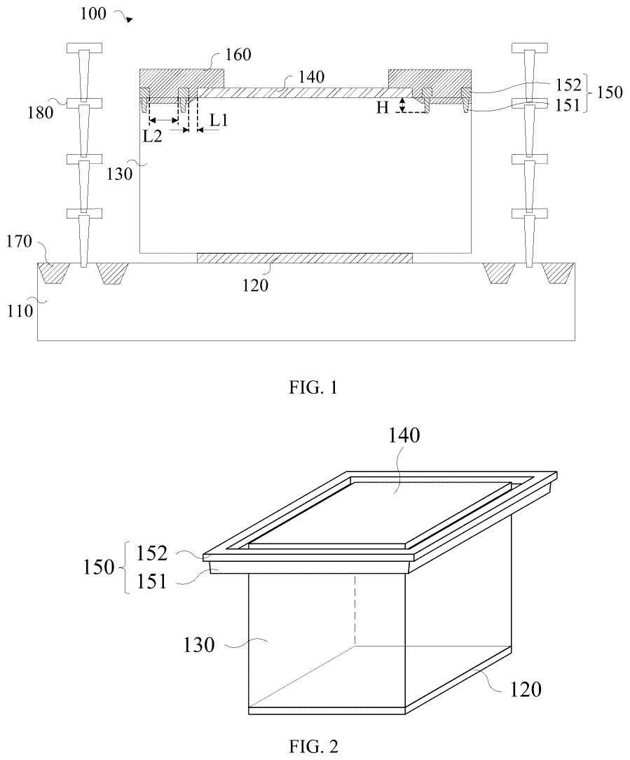

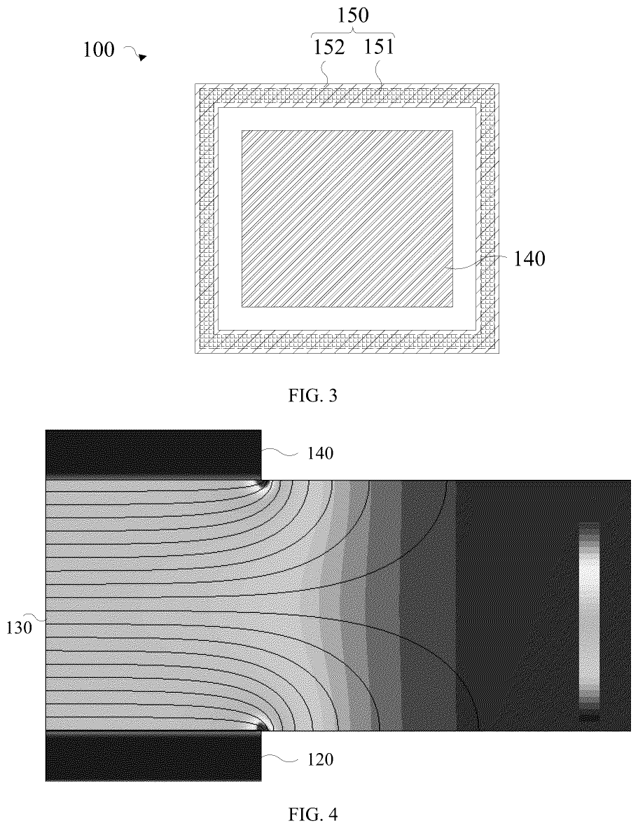

In an embodiment, referring to FIGS. 1, 2, and 3, the metal ring 150 includes a first part 151 and a second part 152 connected to each other. The first part 151 is embedded in the dielectric layer 130, and an upper surface of the first part 151 is flush with an upper surface of the dielectric layer 130. The second part 152 is located on the upper surface of the first part 151, and the second metal layer 140 is located on the upper surface of the dielectric layer 130.

By arranging the metal ring 150 to include the first part 151 and the second part 152, when the metal ring 150 is prepared, the first part 151 and the second part 152 can be prepared separately, thereby reducing difficulty of the preparation of the metal ring 150. For example, firstly, a trench is provided in the dielectric layer 130, and then the trench is filled with metal to form the first part 151. Secondly, the upper surface of the first part 151 is flush with the upper surface of the dielectric layer 130 by using a planarization process. Finally, the second part 152 is formed on the upper surface of the first part 151.

In an embodiment, as shown in FIG. 1, in a thickness direction of the dielectric layer 130, a thickness H of the first part 151 ranges from about 400 nm to about 500 nm. It may be alternatively understood as follows: a thickness of the portion of the metal ring 150 located in the dielectric layer 130 ranges from about 400 nm to about 500 nm. The thickness H of the first part 151 may be about 400 nm, 450 nm, 480 nm, or 500 nm. The thickness H of the first part 151 is located within the above range, which may ensure that the thickness H of the first part 151 is greater than a thickness of the defects on the surface of the dielectric layer 130, and minimize hindrance caused by the defects to the movement of the movable charges between the metal ring 150 and the second metal layer 140, thereby further optimizing the electric field distribution at the edge of the second metal layer 140, reducing the electric field intensity at the edge of the second metal layer 140, increasing the withstand voltage of the semiconductor device 100, preventing premature breakdown of the dielectric layer 130, and prolonging the service life of the semiconductor device 100.

In an embodiment, a thickness of the second part 152 is equal to a thickness of the second metal layer 140, and an upper surface of the second part 152 is flush with an upper surface of the second metal layer 140.

The thickness of the second part 152 refers to a distance from the upper surface of the second part 152 to a lower surface of the second part 152 (or the upper surface of the first part 151). The thickness of the second metal layer 140 refers to a distance from the upper surface of the second metal layer 140 to a lower surface of the second metal layer 140 (or the upper surface of the dielectric layer 130). In this way, the capacitor can be better formed between the metal ring 150 and the second metal layer 140. By use of the field plate effect created by the capacitor, a high-density electric field below the metal ring 150 is evenly dispersed, thereby suppressing a peak of the electric field at the edge of the second metal layer 140, increasing the withstand voltage of the semiconductor device 100, preventing premature breakdown of the dielectric layer 130, and prolonging the service life of the semiconductor device 100.

In an embodiment, as shown in FIGS. 1, 2, and 3, an orthographic projection of the second part 152 on an upper surface of the dielectric layer 130 covers an orthographic projection of the first part 151 on the upper surface of the dielectric layer 130. That is, when viewed in a direction perpendicular to the thickness direction of the dielectric layer 130, a cross-sectional area of the second part 152 is larger than a cross-sectional area of the first part 151. In this way, on the one hand, it can prevent the distance between the first part 151 and the second metal layer 140 from being too small to affect the electric field distribution between the first metal layer 120 and the second metal layer 140. On the other hand, the metal ring 150 in the dielectric layer 130 can be prevented from being too large and affecting the performance of the dielectric layer 130.

In an embodiment, as shown in FIG. 1, a first spacing L1 is defined between the metal ring 150 and the second metal layer 140, where the first spacing L1 ranges from about 2 μm to about 5 μm. For example, the first spacing L1 may be about 2 μm, 3 μm, 3.5 μm, 4.5 m, or 5 μm. The first spacing L1 is set within the above numerical range, the electric field distribution at the edge of the second metal layer 140 can be better optimized, the withstand voltage of the semiconductor device 100 can be increased, premature breakdown of the dielectric layer 130 can be prevented, and the service life of the semiconductor device 100 can be prolonged. When a plurality of metal rings 150 are provided, the first spacing LI refers to a spacing between the second metal layer 140 and the metal ring 150 adjacent to the second metal layer 140.

In an embodiment, as shown in FIG. 1, the semiconductor device 100 includes a plurality of metal rings 150. The plurality of metal rings 150 are arranged around the second metal layer 140 and spaced apart from each other.

With above arrangement, the plurality of metal rings 150 are sleeved on the outer side of the second metal layer 140, so that the plurality of metal rings 150 can optimize the electric field in a wider range, which reduces electric field intensity in a wider range outside the second metal layer 140, increases the withstand voltage of the semiconductor device 100, prevents premature breakdown of the dielectric layer 130, and prolongs the service life of the semiconductor device 100.

In an embodiment, a second spacing L2 is defined between two adjacent metal rings 150. The second spacing L2 may be equal to the first spacing L1.

In this way, the electric field distribution at the edge of the second metal layer 140 can be more uniform, thereby making the electric field intensity at the edge of the second metal layer 140 more uniform, increasing the withstand voltage of the semiconductor device 100, preventing premature breakdown of the dielectric layer 130, and prolonging the service life of the semiconductor device 100.

In an embodiment, as shown in FIG. 1, the semiconductor device 100 further includes a passivation layer 160. The passivation layer 160 is located on a side of the dielectric layer 130 adjacent to the second metal layer 140. The passivation layer 160 covers part of a surface of the second metal layer 140, a surface of the metal ring 150, and an exposed surface of the dielectric layer 130. The passivation layer 160 may play roles in protection and insulation, which prevents an electrical connection between the metal ring 150 and an external device on the one hand, and prevents damages to the metal ring 150 by an external force on the other hand. The passivation layer 160 may be made of silicon oxide, silicon nitride, or the like.

It is to be noted that the first metal layer 120 and the second metal layer 140 have the same shapes, and the shapes of the first metal layer 120 and the second metal layer 140 may be rectangles, ellipses, circles, or the like. In addition, the first metal layer 120 and the second metal layer 140 may have the same size or different sizes.

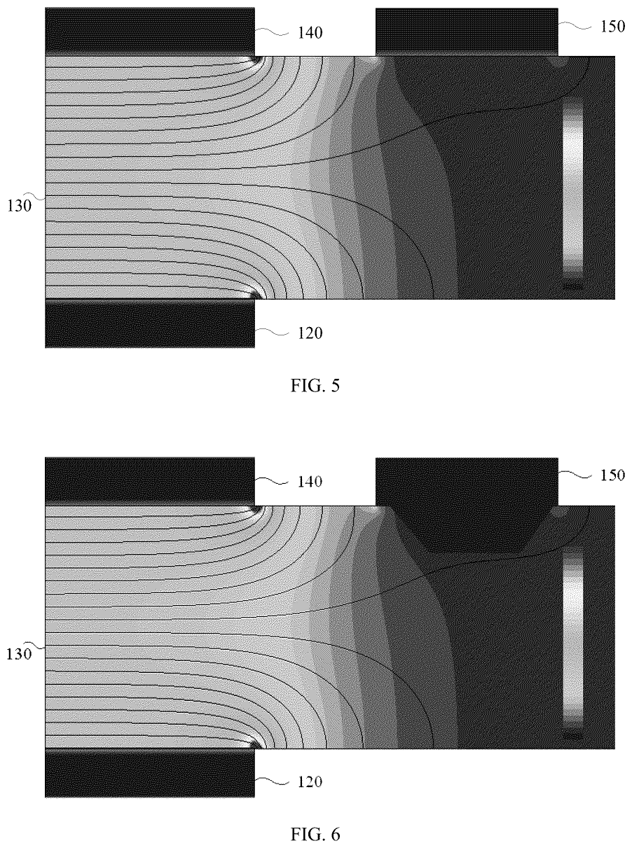

Referring to FIGS. 4 to 6, the inventor respectively simulates electric field distribution of the semiconductor device not provided with the metal ring, electric field distribution of the semiconductor device in which the metal ring 150 is provided on the surface of the dielectric layer 130, and electric field distribution of the semiconductor device in which a portion of the metal ring 150 is located in the dielectric layer 130. FIG. 4 is a schematic view of simulation of electric field distribution of the semiconductor device not provided with the metal ring, FIG. 5 is a schematic view of simulation of electric field distribution of the semiconductor device in which the metal ring 150 is provided on the surface of the dielectric layer 130, and FIG. 6 is a schematic view of simulation of electric field distribution of the semiconductor device in which a portion of the metal ring 150 is located in the dielectric layer 130. By way of comparison, it may be seen that the electric field intensity at the edge of the second metal layer 140 shown in FIG. 5 is less than the electric field intensity at the edge of the second metal layer 140 shown in FIG. 4, and the electric field intensity at the edge of the second metal layer 140 shown in FIG. 6 is less than the electric field intensity at the edge of the second metal layer 140 shown in FIG. 5. In addition, simulation data shows that the breakdown voltage of the semiconductor device shown in FIG. 4 is 60 V, the breakdown voltage of the semiconductor device shown in FIG. 5 is 66 V, and the breakdown voltage of the semiconductor device shown in FIG. 6 is 70 V. As can be seen, arranging a portion of the metal ring 150 in the dielectric layer 130 can significantly optimize the electric field distribution at the edge of the second metal layer 140 and increase the withstand voltage of the semiconductor device.

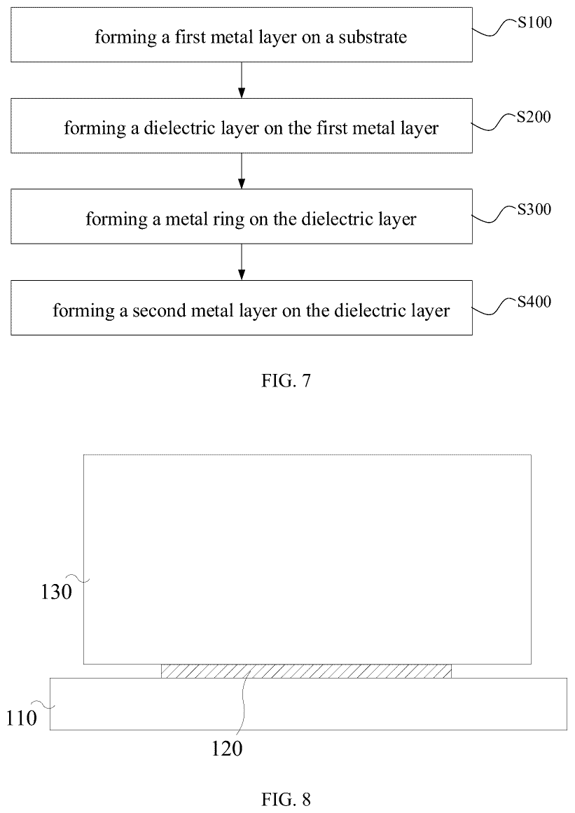

Embodiments of the present application provide a preparation method for a semiconductor device. As shown in FIG. 7, the preparation method for a semiconductor device includes the following steps.

At S100, a first metal layer is formed on a substrate. For example, a pattern of the first metal layer 120 may be formed through a mask, and then the first metal layer 120 may be deposited.

It may be understood that the substrate 110 may be made of monocrystalline silicon, polycrystalline silicon, amorphous silicon, silicon-germanium compound, SOI, LTPS, or the like, or made of other materials known to those skilled in the art. The substrate 110 may provide a supporting foundation for structures on the substrate 110. The first metal layer 120 may be made of copper, aluminum, or any metal or metal alloy suitable for semiconductor processing.

At S200, a dielectric layer is formed on the first metal layer. For example, a pattern of the dielectric layer 130 may be formed through a mask, and then the dielectric layer 130 may be deposited. The dielectric layer 130 may be made of silicon dioxide, silicon nitride, silicon oxynitride, or the like. The metal ring 150 may be made of a same material as the first metal layer 120. A structure obtained after the formation of the dielectric layer 130 is shown in FIG. 8.

At S300, a metal ring is formed on the dielectric layer. A portion of the metal ring 150 is arranged in the dielectric layer 130.

At S400, a second metal layer is formed on the dielectric layer. Both the first metal layer 120 and the second metal layer 140 are configured to be electrically connected to an external circuit. The potential of the second metal layer 140 is higher than the potential of the first metal layer 120. The metal ring 150 is arranged around an outer side of the second metal layer 140. For example, a pattern of the second metal layer 140 may be formed through a mask, and then the second metal layer 140 may be deposited.

According to the above preparation method for a semiconductor device, the metal ring 150 is formed on the dielectric layer 130, so that a capacitor may be formed between the metal ring 150 and the second metal layer 140. This capacitor may create a field plate effect, and an electric field of the capacitor evenly disperses a high-density electric field at the edge of the second metal layer 140, thereby suppressing a peak of the electric field at the edge of the second metal layer 140, increasing a withstand voltage of the semiconductor device 100, preventing premature breakdown of the dielectric layer 130, and prolonging the service life of the semiconductor device 100. In addition, a portion of the metal ring 150 is located in the dielectric layer 130, which is beneficial to movement of movable charges between the metal ring 150 and the second metal layer 140 and minimizes hindrance to the movement of the charges caused by the defects on the surface of the dielectric layer 130, thereby further optimizing the electric field distribution at the edge of the second metal layer 140, reducing the electric field intensity at the edge of the second metal layer 140, increasing the withstand voltage of the semiconductor device 100, preventing premature breakdown of the dielectric layer 130, and prolonging the service life of the semiconductor device 100.

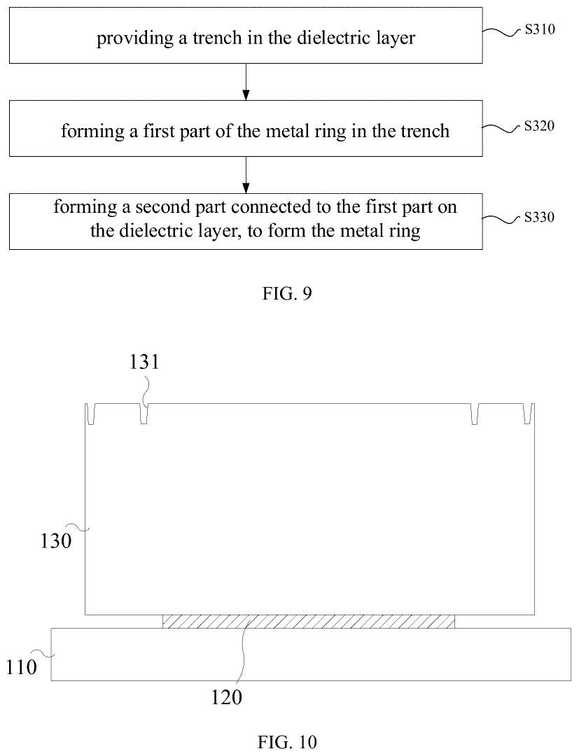

In an embodiment, as shown in FIG. 9, the step S300 of forming the metal ring on the dielectric layer includes the following steps.

At S310, a trench is provided in the dielectric layer. For example, the trench 131 may be formed in the dielectric layer 130 through an etching process. A structure obtained after formation of the trench 131 is shown in FIG. 10.

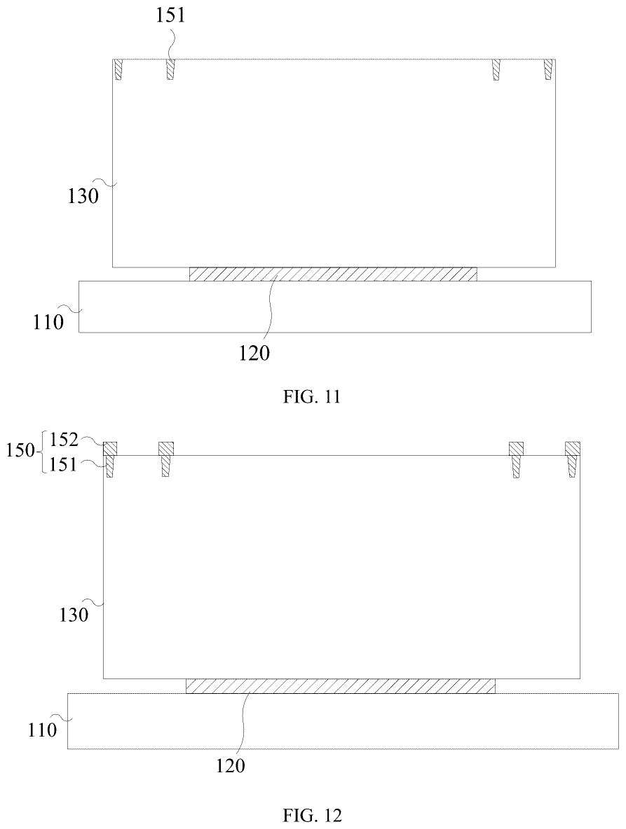

At S320, a first part of the metal ring is formed in the trench. For example, the trench 131 may be filled with metal to fill up the trench 131. It may be understood that after filling, the metal on the surface of the dielectric layer 130 may be removed by using a planarization process, so that the surface of the dielectric layer 130 is flush with a surface of the first part 151. A structure obtained after the formation of the first part 151 is shown in FIG. 11.

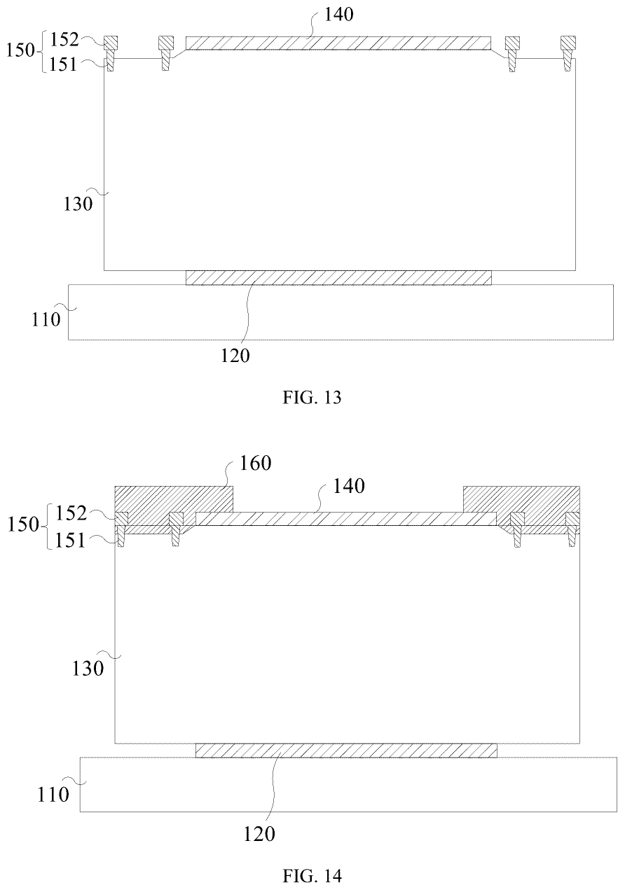

At S330, a second part connected to the first part is formed on the dielectric layer, to form the metal ring. A structure obtained after the formation of the second part 152 is shown in FIG. 12. After this step, a second metal layer 140 may be formed on the dielectric layer 130. A structure obtained after formation of the second metal layer 140 is shown in FIG. 13.

In an embodiment, subsequent to step S400 of forming the second metal layer on the dielectric layer, the preparation method further includes the following step.

At S500, a passivation layer is formed on part of a surface of the second metal layer. The passivation layer 160 further covers a surface of the metal ring 150 and an exposed surface of the dielectric layer 130. The passivation layer 160 may be made of silicon oxide, silicon nitride, or the like. A preparation process of the passivation layer 160 may be the same as the preparation process of the dielectric layer 130, which is not repeatedly described in detail herein in the embodiments of the present application. A structure obtained after the formation of the passivation layer 160 is shown in FIG. 14.

It should be understood that, although the steps in the flowcharts of FIG. 7 are shown in sequence as indicated by the arrows, these steps are not necessarily performed in the order indicated by the arrows. Unless otherwise clearly specified herein, these steps are performed without any strict sequence limitation, and may be performed in other orders. In addition, at least some steps in the flowcharts of FIG. 7 may include a plurality of steps or a plurality of stages, and such steps or stages are not necessarily performed at a same moment, and may be performed at different moments. These steps or stages are not necessarily performed in sequence, and the steps or stages and at least some of other steps or sub-steps or sub-stages of other steps may be performed in turn or alternately.

In the description of the specification, reference terms such as “some embodiments”, “other embodiments”, and “ideal embodiments” mean that a particular feature, structure, material, or characteristic described in connection with the embodiment or example is included in at least one embodiment or example of the present disclosure. In the specification, illustrative descriptions of the above terms do not necessarily refer to a same embodiment or example.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present application, and their description is specific and detailed, but cannot therefore be understood as a limitation on the patent scope of the present application. It should be noted that those of ordinary skill in the art may further make variants and improvements without departing from the conception of the present application. and these all fall within the protection scope of the present application. Therefore. the patent protection scope of the present application should be subject to the appended claims.

1. A semiconductor device, comprising:
a substrate;
a first metal layer disposed on the substrate;
a dielectric layer disposed on a side of the first metal layer away from the substrate;
a second metal layer disposed on a side of the dielectric layer away from the first metal layer, a potential of the second metal layer being higher than a potential of the first metal layer; and
a metal ring disposed on a side of the dielectric layer away from the first metal layer, the metal ring being arranged around an outer side of the second metal layer;
wherein a portion of the metal ring is arranged in the dielectric layer.

2. The semiconductor device according to claim 1, wherein the metal ring includes a first part and a second part connected to each other, the first part being embedded in the dielectric layer, and the second part being located on the side of the dielectric layer away from the first metal layer.

3. The semiconductor device according to claim 2, wherein in a thickness direction of the dielectric layer, a thickness of the first part ranges from about 400 nm to about 500 nm.

4. The semiconductor device according to claim 2, wherein a thickness of the second part is equal to a thickness of the second metal layer, and an upper surface of the second part is flush with an upper surface of the second metal layer.

5. The semiconductor device according to claim 2, wherein an orthographic projection of the second part on an upper surface of the dielectric layer covers an orthographic projection of the first part on the upper surface of the dielectric layer.

6. The semiconductor device according to claim 1, wherein a first spacing is defined between the second metal layer and the metal ring adjacent to the second metal layer, wherein the first spacing ranges from about 2 μm to about 5 μm.

7. The semiconductor device according to claim 6, wherein the semiconductor device includes a plurality of metal rings, the plurality of metal rings being arranged around the second metal layer and spaced apart from each other.

8. The semiconductor device according to claim 7, wherein a second spacing is defined between two adjacent metal rings, the second spacing being equal to the first spacing.

9. The semiconductor device according to claim 1, further comprising a passivation layer arranged on a side of the dielectric layer adjacent to the second metal layer, wherein the passivation layer covers part of a surface of the second metal layer, a surface of the metal ring, and an exposed surface of the dielectric layer.

10. The semiconductor device according to claim 1, further comprising isolation structures arranged on the substrate, wherein a capacitor formed by the first metal layer, the dielectric layer, and the second metal layer is arranged between adjacent isolation structures.

11. A preparation method for a semiconductor device, comprising:
forming a first metal layer on a substrate;
forming a dielectric layer on the first metal layer;
forming a metal ring on the dielectric layer, wherein a portion of the metal ring is arranged in the dielectric layer; and
forming a second metal layer on the dielectric layer, wherein a potential of the second metal layer is higher than a potential of the first metal layer; and the metal ring is arranged around an outer side of the second metal layer.

12. The preparation method according to claim 11, wherein the forming the metal ring on the dielectric layer includes:
providing a trench in the dielectric layer;
forming a first part of the metal ring in the trench; and
forming a second part connected to the first part on the dielectric layer, to form the metal ring.

13. The preparation method according to claim 11, further comprising. subsequent to the forming the second metal layer on the dielectric layer:
forming a passivation layer on part of a surface of the second metal layer. wherein the passivation layer further covers a surface of the metal ring and an exposed surface of the dielectric layer.
